(19) United States
(12) Patent Application Publication
(10) Pub. No.: US 2006/0018182 A1
(43) Pub. Date: Jan. 26, 2006

(54) Solid state microoptoelectromechanical system (moens) for reading photonics diffractive memory

(76) Inventors: Renaud Kieffer, Hoenheim (FR); Yoshitate Takakura, Illkirch (FR); Joel Fontaine, Strasbourg (FR); Idriss El Hafidi, Strasbourg (FR); Romualda Grzymala, Strasbourg (FR); Patrick Meyrueis, Strasbourg (FR)

Correspondence Address: DISCOVISION ASSOCIATES;INTELLECTUAL PROPERTY DEVELOPMENT, 2355 MAIN STREET, SUITE 200, IRVINE, CA, 92614, US

(21) Appl. No.: 10/497,951

(22) PCT Filed: Dec. 7, 2001
(86) PCT No.: PCT/EP01/15421

§ 371 Date: Jun. 7, 2004

(51) Int. Cl. G11C 8/02

(52) U.S. Cl. 365/232

(57) ABSTRACT

The present invention comprises a solid-state system for reading information from a photonics diffractive memory. An acousto-optic deflector directs a convergent light beam onto a micr-mirror array which then reflects the light beam onto the photonics diffractive memory at a predetermined point and angle so as to access a packet of information. The compact architecture for this diffractive optics systems in accordance with the present invention integrates a number of components into a compact package, including an acousto-optic deflector and a microoptoelectromechanical system (MOEMS) mirror array whose elements oscillate with a sznchronized frequency adapted to that of the acousto-optic deflector. This architecture reduces the addressing component of a reading system for a photonics diffractive memory to a matchbox size.

### FIELD OF THE INVENTION

The present invention generally relates to a photonics diffractive memory. In particular, the present invention relates to an apparatus for reading information from the photonics diffractive memory.

### BACKGROUND OF THE INVENTION

The large storage capacities and relative low costs of CD-ROMS and DVDs have created an even greater demand for still larger and cheaper optical storage media. Holographic memories have been proposed to supersede the optical disc as a high-capacity digital storage medium. The high density and speed of the holographic memory comes from three-dimensional recording and from the simultaneous readout of an entire packet of data at one time. The principal advantages of holographic memory are a higher information density (10¹¹ bits or more per square centimeter), a short random access time (˜100 microseconds and less), and a high information transmission rate (10⁹ bit/sec).

In holographic recording, a light beam from a coherent monochromatic source (e.g., a laser) is split into a reference beam and an object beam. The object beam is passed through a spatial light modulator (SLM) and then into a storage medium. The SLM forms a matrix of shutters that represents a packet of binary data. The object beam passes through the SLM which acts to modulate the object beam with the binary information being displayed on the SLM. The modulated object beam is then directed to one point on the storage medium by an addressing mechanism where it intersects with the reference beam to create a hologram representing the packet of data.

An optical system consisting of lenses and mirrors is used to precisely direct the optical beam encoded with the packet of data to the particular addressed area of the storage medium. Optimum use of the capacity of a thick storage medium is realized by spatial and angular multiplexing. In spatial multiplexing, a set of packets is stored in the storage medium shaped into a plane as an array of spatially separated and regularly arranged subholograms by varying the beam direction in the x-axis and y-axis of the plane. Each subhologram is formed at a point in the storage medium with the rectangular coordinates representing the respective packet address as recorded in the storage medium. In angular multiplexing, recording is carried out by keeping the x- and y-coordinates the same while changing the irradiation angle of the reference beam in the storage medium. By repeatedly incrementing the irradiation angle, a plurality of packets of information is recorded as a set of subholograms at the same x- and y-spatial location.

Previous holographic devices for recording information in a highly multiplexed volume holographic memory, and for reading the information out, require components and dimensions having a large size which places a limit on the ability to miniaturize these systems. Because previous holographic devices use motors and large-scale components such as mirrors and lenses, the addressing systems of these previous devices are slow. Furthermore, the mechanical components of these previous devices need frequent maintenance to correct errors and dysfunction coming, for instance, from wear and friction (i.e., tribology effect). Furthermore, previous addressing systems are expensive because they use complex systems for control. Thus, their prices cannot be lowered by mass production. Moreover, previous devices are not economical in their energy consumption. Even when previous addressing devices are accurate when new, the wear and friction of the interacting surfaces that are in relative motion lowers their accuracy with time.

In view of the foregoing, it would be desirable to provide one or more techniques which overcomes the above-described inadequacies and shortcomings of the above-described proposed solutions.

### OBJECTS OF THE INVENTION

In view of the foregoing, it is an object of the present invention to provide an improvement in higher speed and smaller size of photonics diffractive memory reading systems.

It is a further object of the present invention to provide a miniaturization of a photonics diffractive memory reading system.

It is another object of the present invention to reduce the addressing system of a photonics diffractive memory reading system to a matchbox size.

It is a still a further object of the present invention to design a solid state reading system that can be rapidly manufactured in large quantities and low cost out of existing resources.

### SUMMARY OF THE INVENTION

In order to achieve the above-mentioned objectives, the present invention comprises a solid-state system for reading information from a photonics diffractive memory. A coherent light source generates a convergent light beam which is then deflected by an acousto-optic deflector. A plurality of micro-mirrors receives the deflected light beam from the acousto-optic deflector at one of the micro-mirrors. A photonics diffractive memory having a plurality of points receives at one of the points the reflected light beam which is reflected from the micro-mirror. A detector has a plurality of light-detecting cells. At least one of the cells receives a portion of the reflected light beam transmitted through the point.

In a further aspect of the present invention, the micro-mirrors are configured as a matrix.

In another aspect of the present invention, there is a lens which forms the convergent light beam from the light source.

In still another aspect of the present invention, the convergent light source is selected from the group consisting of a low power laser and a light-emitting diode.

In yet another aspect of the present invention, the detector is a CCD detector array.

In a further aspect of the present invention, each of the plurality of points stores one or more diffraction patterns.

In yet another aspect of the present invention, the photonics diffractive memory comprises stored therein information located at the plurality of points of the memory and at a plurality of angles at each one of the points so as to form a plurality of packets of information at each one of the points.

In another aspect of the present invention, each of the micro-mirrors is a oscillatory scanning micro-mirror.

In a further aspect of the present invention, a computer is configured to coordinate the synchronization of the acousto-optic deflector and the oscillatory micro-mirrors so that the reflected light beam is directed to one of the points with a specific angle for a sufficient time to retrieve information from the point.

In yet another aspect of the present invention, each of the micro-mirrors is a oscillatory micro-mirror and the oscillation cycle of the micro-mirror is coordinated with the scanning of the acousto-optical deflector so as to direct said reflected light beam onto one of the points of the storage medium.

### BRIEF DESCRIPTION OF THE DRAWINGS

In order to facilitate a fuller understanding of the present invention, reference is now made to the appended drawings. These drawings should not be construed as limiting the present invention, but are intended to be exemplary only.

FIG. 1 shows a micro-mirror assembly according to the present invention.

FIG. 2 shows a perspective view of a micro-mirror assembly according to the present invention.

FIG. 2a shows a close up view of the actuator of the micro-mirror assembly according to the present invention.

FIG. 3a shows adding an epitaxial layer to a wafer as part of the MEMS fabrication process according to the present invention.

FIG. 3b shows the formation of the starting electrodes and deposition of a metal layer as part of the MEMS fabrication process according to the present invention.

FIG. 3c shows an anisotropical etch to remove the substrate underneath the designed mirror plate as part of the MEMS fabrication process according to the present invention.

FIG. 3d shows a cross section of the micro-mirror chip according to the present invention.

FIG. 4a shows a starting electrode of a micro-mirror assembly according to the present invention.

FIG. 4b shows operation of a micro-mirror being driven by a saw tooth signal according to the present invention.

FIG. 5 shows a solid state reading system according to the present invention.

FIG. 6 shows an acousto-optic deflector according to the present invention.

FIG. 7 shows a schematic representation of a diffractive optics recording process

FIG. 8 shows a matrix of points forming a storage medium according to the present invention.

FIG. 9 shows synchronization of the mirror of the solid state reading system according to the present invention.

### DETAILED DESCRIPTION OF THE INVENTION

The compact architecture for diffractive optics systems in accordance with the present invention integrates a number of components into a compact package, including an acousto-optic deflector and a microoptoelectromechanical system (MOEMS) device which reduces the addressing component of a reading system for a photonics diffractive memory to a matchbox size. The reading system is made of solid-state components. The mirrors are built in CMOS technology resulting in the advantage that the reading system can be mass-produced at low cost.

Various diffractive recording/reading processes have been developed in the art and further details can be found in the book Holographic Data Storage, Springer (2000) edited by H. J. Coufal, D. Psaltis, and G. T. Sincerbox. In this specification, the term “diffractive” is used throughout to differentiate prior art holographic technology used for 3-D image generation from diffractive technology necessary for the generation of a storage medium. For example, diffraction efficiency is critical to the viability of any material to be used as a diffractive storage medium. The quality of interference constituting a 3D-hologram is simple to achieve compared to the quality required to realize a storage medium. Moreover, a storage diffractive pattern can also be implemented by using other techniques than the interference of a reference and object beam, such as using as an e-beam etched on a material to generated diffraction patterns. For all these reasons, the specification herein introduces the concept of a broader diffractive optics technology.

FIG. 1 shows a top view of a scanning micro-mirror element 100 comprising a mirror plate 102 suspended by two or four torsional springs 122a, 122b which connect the mirror plate 102 to anchors 120a, 120b, respectively. The anchors 120a, 120b are attached to the substrate 110. The two comb like driving electrodes 105a, 105b create torque to move the mirror plate 102. The mirror plate 102 of FIG. 1 is an example of a microoptoelectromechanical system (MOEMS). A MEOMS is a system which combines electrical and mechanical components, including optical components, into a physically small size.

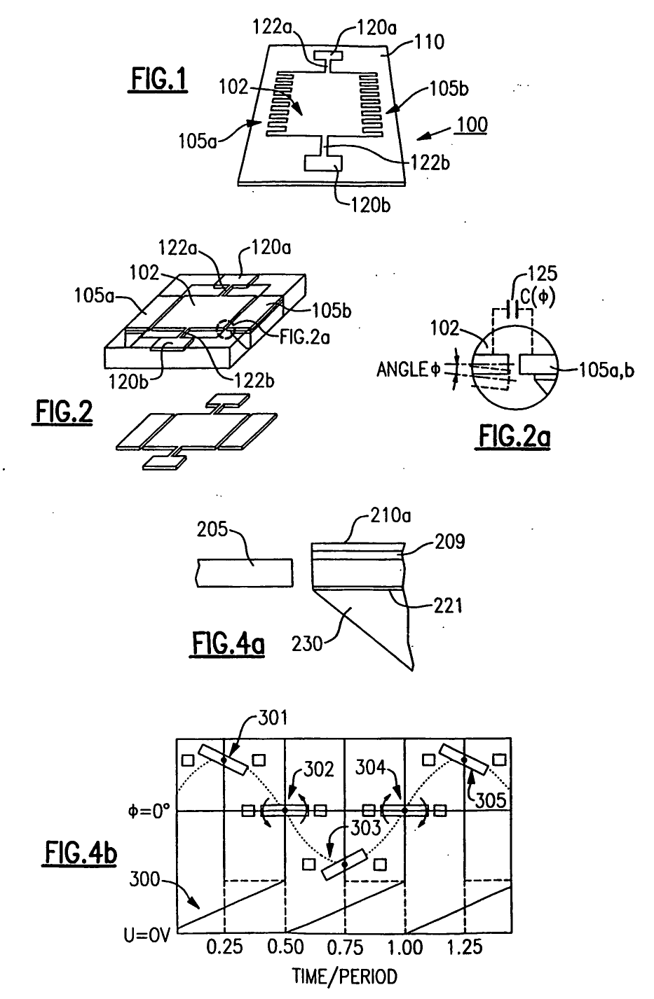

FIG. 2 shows a perspective view of the micro-mirror element 100 comprising the mirror plate 102 cut in a silicon substrate on which a reflected film is deposited, typically a film of aluminum with a typical thickness of about fifty nanometers. The plate 102 is suspended from the two or four twisting points 120a, 120b and is actuated by the two or four drive electrodes 105a, 105b, depending on whether it is desired to have the mirror 102 rotates in one or two directions. The angle of deflection is in theory unlimited, but in practice it is about 60°.

The variation of the capacitance C 125 (C varies with angle φ) between the mirror plate 102 and the comb like driving electrodes 105a, 105b is used to generate the plate tortional movement. If a voltage U is applied by an energy source (not shown) to the driving electrodes 105a, 105b, the generated electrostatic torque M is:
M=½dC/dφU²
where φ is the deflection angle of the plate.

The mirror plate 102 can have a size from 0.5×0.5 mm up to 3×3 mm. The actuators (the movement between mirror plate 102 and electrodes 105 as driven by the energy source) are resonantly excited, i.e., they are continuously oscillating. The scan frequency depends on the size of the mirror plate (0.14 KHz up to 20 KHz) and a mechanical scan angle of ±15° can be achieved at a driving voltage of only 20V.

When the actuator works in synchronous mode, it is possible to control the angular position of the mirror plate 102 by controlling the maximum deflection amplitude and oscillating period. Advantages of these mirrors is that the amplitude of the deflection can be monitored with the driving voltage U. For a large scan angle, the deflection angle varies linearly with the excitation voltage.

As shown in FIG. 2A, the space lying between the mirror plate 102 and the drive electrodes 105a, 105b forms a variable capacitor. Thus, applying a voltage generates electrostatic torque acting on the plate and causing it to rotate and/or oscillate. Given the particularly small size of these micro-mirrors on the one hand, but also their mode of operation on the other, it becomes possible to reduce the size of the read device 400 (see FIG. 5) significantly and hence achieve a very high level of integration.

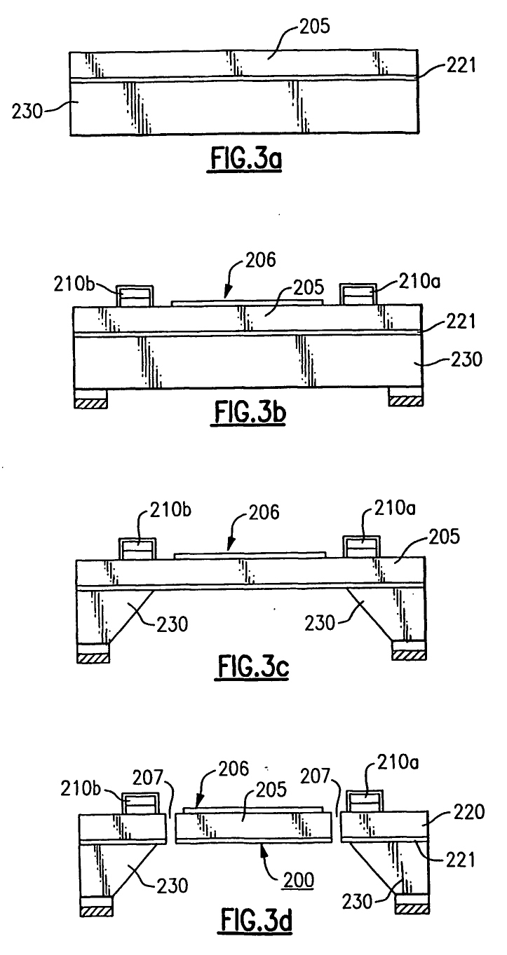

FIGS. 3a-3d show the process for manufacturing a micro-mirror element 200 on a substrate 230 with starting electrodes 210a, 210b. The fabrication is achieved using a CMOS-compatible technology. Referring to FIG. 3a, a wafer 230 serves as the base material. A buried oxide (BOX) layer 221 is produced in a SIMOX (Separation by Implantation of Oxygen) process. A 200-nm-thick silicon layer 205 on top of the BOX 221 is strengthened by a 20 um thick epitaxial layer. Referring to FIG. 3b, an oxide and a metal layer are deposited and patterned to form the starting electrodes 210a, 210b. The metal layer is protected by an additional oxide. In the next step a 50-nm-thick layer 206 of Al is deposited forming the reflective coating in the mirror area. Referring to FIG. 3c., the substrate underneath the designed torsional springs and the mirror plate 205 is removed by an anisotropical etch in a tetramethylammonium hydroxide (TMAH) solution leaving the remaining portions 230. TMAH is a chemical solution used for antisotropical etching of the wafer substrate in which the micro mirrors are etched. After that the BOX layer is removed and the epitaxial layer is patterned using the Advanced Silicon Etch™-process, trenches 207 are formed. A cross section of the micro-mirror chip 200 at the end of the process is shown in FIG. 3d.

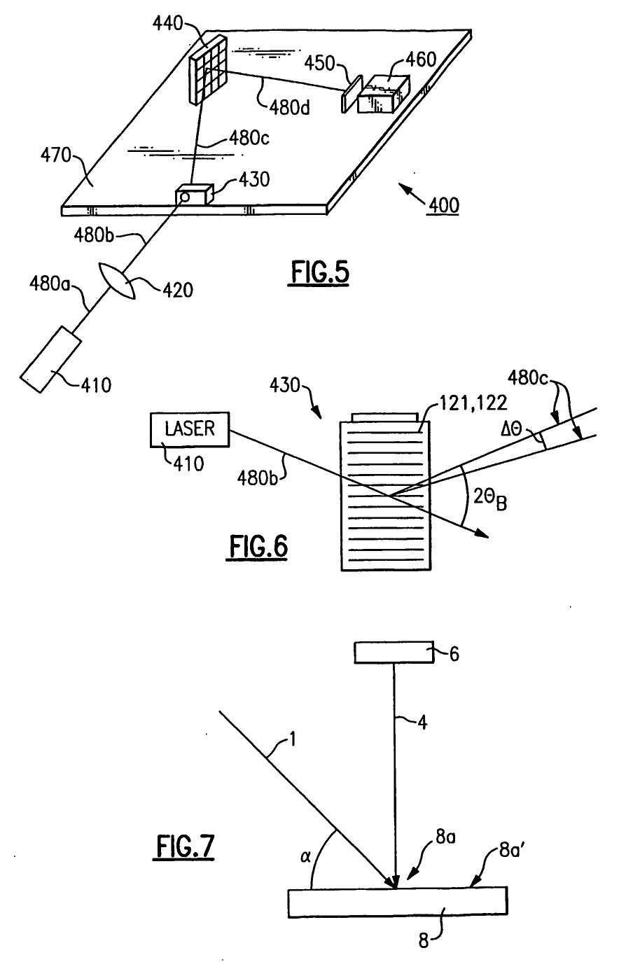

FIG. 4a illustrates the operation of the micro-mirror element 100. FIG. 4a shows the starting electrodes 210a used to start a motion of the mirror plate 205. A voltage of a fixed frequency is applied on the starting electrode 210a which yield asymmetries. Assuming perfect symmetry of the actuator it is impossible to start the oscillation without external induced forces. Therefore, there is an additional starting electrode 210a, 210b which is located on top of each of the driving electrodes 221 and isolated from it by an oxide 209. These electrodes 210a, 210b can be contacted separately and break the symmetry of the configuration. Once oscillation is initiated, the mirror actuation works in a synchronized mode where the mirror plate 205 oscillates in phase with the driving excitation of the voltage U generated by an energy source.

FIG. 4b shows synchronization of the mirror plate 102 as driven by a saw tooth signal 300. The saw tooth signal 300 comprises the voltage U applied with a predetermined frequency per second. The operation of the mirror plate 102 is shown at five different positions 301-305 as the mirror plate 102 is driven by saw tooth wave 300 applied across the drive electrodes 105a, 105b (see FIG. 1). In a full cycle comprising a movement from a positive angle, to zero degrees, to a negative angle, the mirror element 102 moves from positions 301 to 304 (a full cycle) and then begins the cycle again at position 305.

Table 1 shows the eigenfrequency (resonance frequency) of the micro-mirror element 100 as a function of mirror size. The eigenfrequency depends on the mechanical and electrical characteristics of the micro-mirror element 100. In the synchronized mode, the mirror oscillates at two times the eigenfrequency.

TABLE 1

| | | | | | |
|---|---|---|---|---|---|
| 1D Mirror | 0.5 | 1 | 1.5 | 2 | 3 |
| size (mm) | | | | | |
| Resonance | 2.32 | 0.4-7.5 | .25-2.5 | .14-1.5 | .2 |
| frequency | | | | | |
| (Khz) | | | | | |

FIG. 5 shows a reading system 400 comprising a separate unit on a platform 470 supporting an acousto-optic deflector 430, a microoptoelectromechanical systems (MOEMS) matrix 440, a matrix memory 450, and an image sensor 460, such as a CCD (charge-coupled device) detection system or other such image detection system. Additional devices located on or off the platform 470 comprise a light source 410 (e.g., a laser, laser diode) and a converging lens 420.

The operation of the reading system proceeds with the light source 410 emitting a light beam 480a which is focused by the converging lens 420 from a plane wave to spherical wave 480b. The spherical wave 480b is a convergent beam. The convergent beam 480b is deflected by the acousto-optic deflector 430 to form beam 480c which impinges on one of the micro-mirror elements of the MEOMS matrix 440. The MEOMS mirror matrix 440 has a size that fits the constraints of the memory matrix addressing system. The matrix of micro-mirrors 440 is used to address the matrix of points of the memory 450 in which data are recorded by spatial and angular multiplexing. The beam 480c coming from the acousto-optic deflector 430 forms an area with a diameter that can fit within the diameter of each one of the mirror elements of the MEOMS matrix 440. Additionally, the memory matrix 450 is spatially adjusted in such a way that the size of the laser beam 480d fits exactly the size of every point of the memory matrix 450.

FIG. 6 shows the acousto-optic deflector 430 in greater detail. The acousto-optic (AO) deflector 430 directs the laser beam 480b at an angle to the micro-mirror array 440. When acousto-optical crystals are subjected to stress, especially by means of a transducer usually consisting of a piezoelectric crystal, they modify the angle of diffraction of the light and, in general, of the electromagnetic wave which passes through them in order to modify the value of the diffraction angle of the emerging beam 480 c. Thus, modifying the actuating frequency of the piezoelectric transducer deflects the light beam 480b to form the light beam 480c at one of a plurality of angles.

Thus, as shown in FIG. 6, the variations in orientation along OX and OY (referring to the rectilinear co-ordinates of FIG. 2) of the incident read beam 480b emanating from the low-power laser 410 are obtained by subjecting this beam to two acousto-optic components 121, 122. Consequently it may be understood that, by varying the vibration frequency of the piezoelectric crystal associated with the acousto-optic component(s), it becomes possible to modify, very rapidly, the desired orientation of the grating within the rows and columns of the data-carrying matrix 450. The limiting factor then becomes the response time of the mirror elements of the MEOMS matrix 440 which act on the angle of incidence of the read beam.

FIG. 7 and FIG. 8 describe the contents of the diffractive storage medium. Referring to FIG. 7, in forming a diffractive pattern, or alternately a hologram, a reference beam 1 intersects with an object beam 4 to form a sub-hologram 8a (referred to alternately as a point) extending through the volume of storage medium 8. There is a separate sub-hologram or point 8 a extending through the volume for each angle and spatial location of the reference beam 1. The object beam 4 is modulated with a packet of information 6. The packet 6 contains information in the form of a plurality of bits. The source of the information for the packet 6 can be a computer, the Internet, or any other information-producing source. The hologram impinges on the surface 8 a of the storage medium 8 and extends through the volume of the storage medium 8. The information for the packet 6 is modulated onto the storage medium 8 by spatial multiplexing and angle multiplexing. Angle multiplexing is achieved by varying the angle a of the reference beam 1 with respect to the surface plane of the storage medium 8. A separate packet 6 of information is recorded in the storage medium 8 as a sub-hologram for each chosen angle a and spatial location. Spatial multiplexing is achieved by shifting the reference beam 1 with respect to the surface of the storage medium 8 so that the point 8a shifts to another spatial location, for example point 8a′, on the surface of the storage medium 8.

The storage medium 8 is typically a three-dimensional body made up of a material sensitive to a spatial distribution of light energy produced by interference of the object light beam 4 and the reference light beam 1. A hologram may be recorded in a medium as a variation of absorption or phase or both. The storage material must respond to incident light patterns causing a change in its optical properties. In a volume hologram, a large number of packets of data can be superimposed, so that every packet of data can be reconstructed without distortion. A volume (thick) hologram may be regarded as a superposition of three dimensional gratings recorded in the depth of the layer of the recording material each satisfying the Bragg law (i.e., a volume phase grating). The grating planes in a volume hologram produce change in refraction and/or absorption.

Several materials have been considered as storage material for optical storage systems because of inherent advantages. These advantages include a self-developing capability, dry processing, good stability, thick emulsion, high sensitivity, and nonvolatile storage. Some materials that have been considered for volume holograms are photorefractive crystals, photopolymer materials, and polypeptide material.

Referring now to FIG. 8, there is shown in greater detail the storage medium 8 arranged in the form of a flat sheet, herein referred to as a matrix. In this example, the matrix is 1 cm². Each of a plurality of points on the matrix is defined by its rectilinear coordinates (x, y). An image-forming system (not shown) reduces the object beam 4 to the sub-hologram 8a having a minimum adopted size at one of the x, y point of the matrix. A point in physical space defined by its rectilinear coordinates contains a plurality of packets 8b.

In this case, a 1 mm² image 8a is obtained by focusing the object beam 4 onto the storage medium 8 centered at its coordinate. Due to this interference between the two beams 1,4, a diffractive image 8a 1 mm² in size is recorded in the storage material 8 centered at the coordinates of the matrix. Spatial multiplexing is carried out by sequentially changing the rectilinear coordinates. The object beam 4 focuses on the storage material 8 so that a separate image 8a is recorded at a unique position in the plane defined by its coordinates (x, y). This spatial multiplexing results in a 10 by 10 matrix of diffractive images 8a. Angle multiplexing is carried out by sequentially changing the angle of the reference beam 1 by means of the mirror elements of the MEOMS matrix 440. Angle multiplexing is used to create 15-20 packets of information 8b corresponding to 15 discrete variations of the angle of incidence of the reference beam. Additionally, it is possible to reach 20-25 packets by simple multiplexing and 40-50 packets by using double symmetrical angular multiplexing. A data packet is reconstructed by shinning the reference beam 1 at the same angle and spatial location in which the data packed was recorded. The portion of the reference beam 1 diffracted by the storage material 8 forms the reconstruction, which is typically detected by a detector array. The storage material 8 may be mechanically shifted in order to store data packets at different points by its coordinates (x, y).

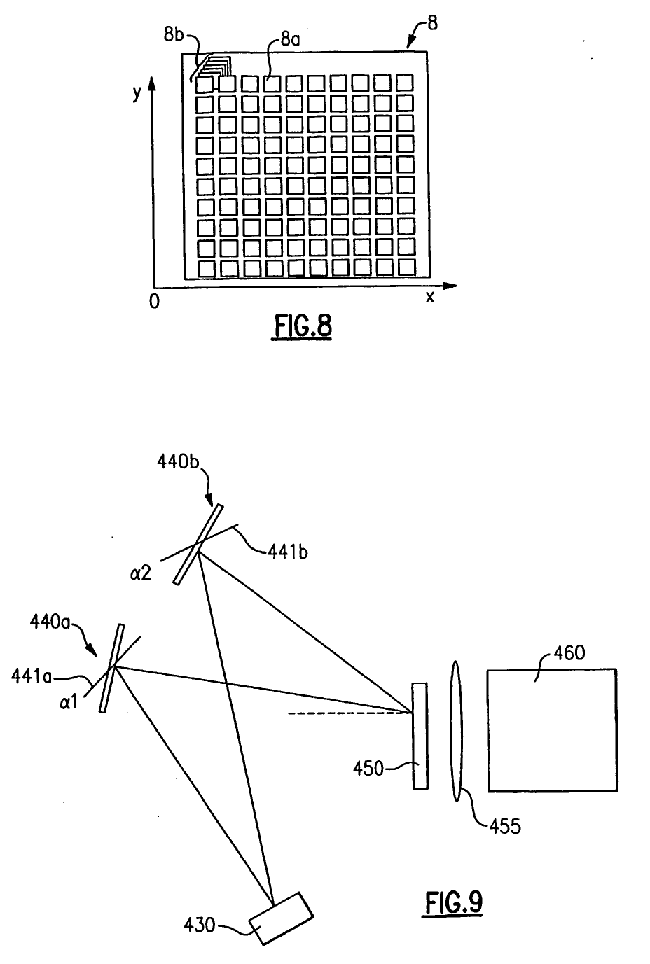

FIG. 9 shows synchronization of the micro-mirrors 440. Because the micro-mirrors 440 are continuously oscillating, it is necessary to synchronize the acousto-optic deflector (AOD) 430 and the micro-mirrors 440 in order to realize the addressing of a data packet of the memory 450. By knowing mirrors parameters like amplitude of deflection and oscillating period, it is possible to control the switching time of the AOD 430. This way, one of the micro-mirrors can be accessed which addresses a desired position on the memory 450. The AOD 430 redirects the laser beam on a chosen mirror at a given time.

Two representative micro-mirrors 440a, 440b of the micro-mirror array 440 of FIG. 5 are shown with each of the micro-mirrors at a different position. The rest position 441a is shown for the micro-mirror 440a. The rest position 441b is shown for the micro-mirror 440b. The coherent laser beam is directed by the AOD 430 at different times to one of the micro-mirrors 440a, 440b which reflect the light beam at a predetermined location and angle to the memory 450. The lens 455 focuses the light energy onto the CCD array 460. A CPU (not shown), such as a computer, microcontroller, or other such control device, controls the AOD 430, the micro-mirrors 440, and the CCD detector 460. The CPU (not shown) receives inputs from sensors indicating the positions of the micro-mirrors 440a, 440b and receives inputs on the state of the AOD 430. The CPU (not shown) then controls the mirror positions of the micro-mirrors 440 and the deflection angle of the AOD 430. Synchronization of the micro-mirrors 440 with the AOD 430 is necessary to reach a maximum deflection angle. The maximum deflection angle is the maximum angle that can be reached by the processed beam. This means that the output beam of the acousto-optic device can reach a maximum value. Between the positive and negative value of this maximum will lie the angular range of the acousto-optic device. An other advantage of synchronization is that the maximum deflection can be monitored by the driving voltage control . That is, the deflection varies linearly with the driving excitation voltage U.

FIG. 9 illustrates synchronization between the micro-mirrors 440, the AOD 430 and the CCD camera 460. The synchronization is shown for two of the micro-mirrors 440a, 440b of the micro-mirror array 440. Because the micro-mirrors 440a, 440b are continuously oscillating at low frequencies (i.e., 200 Hz), the micro-mirrors 440a, 440b can be considered as fixed mirrors compared to the switching time of the AOD (10 to 100 μs). At a switching time T, the micro-mirrors positions can be monitored so that the it is determined how to access a specific packet-of information from the memory 450. In the present invention, the CPU (not shown) controls the mirror synchronization and calculates the switching time of the AOD 430 and the CCD 460 to read a given packet of the memory 450. The positions of the micro-mirrors 440 are calculated to address every packet of the memory 450. At a time T1, the AOD 430 is switched to address the micro-mirror 440a to read a packet of the memory 450. At another time T2, the AOD 430 is switched to address the micro-mirror 440b to read a packet of the memory 450. The micro-mirror 440a is shown at an angle α1 from the normal position 441a. The micro-mirror 440b is shown at an angle α2 from the normal position 441b. The lens 455 focuses the output waveform carrying the data packets onto the array of the CCD camera 460.

The present invention is not to be limited in scope by the specific embodiments described herein. Indeed, various modifications of the present invention, in addition to those described herein, will be apparent to those of skill in the art from the foregoing description and accompanying drawings. Thus, such modifications are intended to fall within the scope of the appended claims.

What is claimed is:

1. A solid-state apparatus for reading information from a photonics diffractive memory, comprising:
a coherent light source configured to generate a convergent light beam;
an acousto-optic deflector configured to deflect said convergent light beam;
a plurality of micro-mirrors configured to receive said deflected light beam from said acousto-optic deflector at one of said micro-mirrors;
a photonics diffractive memory having a plurality of points configured to receive at one of said points said reflected light beam which is reflected from said micro-mirror; and
a detector having a plurality of light-detecting cells, at least one of said cells receiving a portion of said reflected light beam transmitted through said point.

2. The apparatus of claim 1, wherein said micro-mirrors are configured as a matrix.

3. The apparatus of claim 1, further comprising:
a lens for forming said convergent light beam from said light source.

4. The apparatus of claim 1, further comprising:
said convergent light source is selected from the group consisting of a low power laser and a light-emitting diode.

5. The apparatus of claim 1, wherein said detector is a CCD detector array.

6. The apparatus of claim 1, wherein each of said plurality of points stores one or more diffraction patterns.

7. The apparatus of claim 1, wherein said photonics diffractive memory comprises stored therein information located at said plurality of points of said memory and at a plurality of angles at each one of said points so as to form a plurality of packets of information at each one of said points.

8. The apparatus of claim 1, wherein each of said micro-mirrors is an oscillatory scanning micro-mirror.

9. The apparatus of claim 8, further comprising:
a computer configured to coordinate the synchronization of said acousto-optic deflector and said oscillatory micro-mirrors so that said reflected light beam is directed to one of said points for a sufficient time to retrieve information from said point.

10. The apparatus of claim 1 wherein each of said micro-mirrors is an oscillatory micro-mirror and the oscillation cycle of said micro-mirror is coordinated with the scanning of said acousto-optical deflector so as to direct said reflected light beam onto one of said points of said storage medium.

11. A solid-state method for reading information from a photonics diffractive memory, comprising:
generating a light beam;
converging said light beam;
deflecting said convergent light beam towards a plurality of micro-mirrors;
reflecting from one of said plurality of micro-mirrors said convergent light beam received from said acousto-optic deflector to a photonics diffractive memory comprising a plurality of points; and
detecting a portion of said reflected light beam carrying information from one of said points illuminated by said reflected light beam.

12. The method of claim 11, wherein said deflecting is accomplished with an acousto-optics deflector.

13. The method of claim 11, wherein said micro-mirrors are configured to form a matrix.

14. The method of claim 11, further comprising:
a lens for forming said convergent light beam from said light source.

15. The method of claim 11, wherein said convergent light source is selected from the group consisting of a low power laser and a light-emitting diode.

16. The method of claim 11, wherein said detecting is accomplished with a CCD detector array.

17. The method of claim 11, wherein each of said plurality of points stores at least one diffraction pattern.

18. The method of claim 11, wherein said photonics diffractive memory comprises stored therein information located at said plurality of points of said memory and at a plurality of angles at each one of said points so as to form a plurality of packets of information at each one of said points

19. The method of claim 11, wherein each of said micro-mirrors is an oscillatory scanning micro-mirror.

20. The method of claim 19, further comprising:
coordinating the synchronization of said acousto-optic deflector and each of said oscillatory micro-mirrors so that said reflected light beam is directed to one of said points for a sufficient time to retrieve information from said point.

21. The method of claim 11 wherein each of said micro-mirrors is a oscillatory micro-mirror and the oscillation cycle of said micro-mirror is coordinated with the scanning of said acousto-optical deflector so as to direct said reflected light beam onto one of said points of said memory.
